(19) United States
(12) Patent Application Publication
(10) Pub. No.: US 2012/0329369 A1
(43) Pub. Date: Dec. 27, 2012

(54) SUBSTRATE PROCESSING METHOD AND SUBSTRATE PROCESSING APPARATUS

(75) Inventors: Noriko SHIMIZU, Yokohama-shi (JP); Shinya TAKYU, Saitama-ken (JP)

(73) Assignee: Kabushiki Kaisha Toshiba, Tokyo (JP)

(21) Appl. No.: 13/420,944

(22) Filed: Mar. 15, 2012

(30) Foreign Application Priority Data
Jun. 27, 2011 (JP) 2011-141814

(51) Int. Cl. H01L 21/463

(52) U.S. Cl. 451/28; 451/364

(57) ABSTRACT

According to one embodiment, a substrate processing method will be disclosed. The method includes attaching a substrate to be processed onto a supporting substrate via an adhesive layer, removing an outer peripheral edge portion of the substrate to be processed together with the adhesive sticking to the outer peripheral edge portion, and grinding a surface of a side opposite to the supporting substrate of the substrate to be processed whose outer peripheral edge portion is removed.

### CROSS-REFERENCE TO RELATED APPLICATION

This application is based upon and claims the benefit of priority from the prior Japanese Patent Application No. 2011-141814, filed on Jun. 27, 2011; the entire contents of which are incorporated herein by reference.

### FIELD

Embodiments described herein relate generally to a substrate processing method and a substrate processing apparatus.

### BACKGROUND

As a method for thinning (processing) a semiconductor wafer (substrate to be processed), there is known a method in which the semiconductor wafer is attached to a thick supporting substrate with an adhesive and then is ground. This is in order to keep a flatness of the semiconductor wafer during grinding thereof by attaching the semiconductor wafer to the thick supporting substrate, and the semiconductor wafer can be thinned sufficiently evenly to be a thickness of e 100 μm or less.

However, in the above method, when the semiconductor wafer is attached to the supporting substrate, the adhesive is prone to be pressed out to a surrounding area of the semiconductor wafer. The pressed-out adhesive may remain in the surrounding area of the semiconductor wafer after being thinned to induce a problem of contamination of a wafer surface by fine particles or a volatile component. The adhesive may also damage a grinding wheel in the process of grinding to reduce its operating life characteristic. Further, in a case where a dicing tape is applied to the semiconductor wafer to release the supporting substrate after grinding, the adhesive remaining in the surrounding of the semiconductor wafer may stick to the dicing tape, making the supporting substrate hard to be released.

In the method in which the semiconductor wafer is attached to the supporting substrate and ground, if a thickness of the semiconductor wafer is tried to be thinned to, for example, 100 μm or less, there is an apprehension that a knife edge is formed in an outer peripheral edge of the semiconductor wafer thereby causing a wafer crack. Therefore, usually, an outer peripheral edge portion of the semiconductor wafer is edge-trimmed before being attached to the supporting substrate. The aforementioned press-out of the adhesion is apt to occur in such an edge-trimmed semiconductor wafer in particular.

### BRIEF DESCRIPTION OF THE DRAWINGS

FIG. 1A to FIG. 1C are schematic cross-sectional views illustrating a substrate processing method according to an embodiment.

FIG. 2A to FIG. 2D are schematic cross-sectional views illustrating a substrate processing method according to another embodiment.

FIG. 3 is a top view illustrating a substrate to be processed in the course of being processed according to another embodiment.

FIG. 4A to FIG. 4D are schematic cross-sectional views illustrating a modification example of a substrate processing method according to another embodiment.

### DETAILED DESCRIPTION

In general, according to one embodiment, a substrate processing method will be disclosed. The method includes attaching a substrate to be processed onto a supporting substrate via an adhesive layer, removing an outer peripheral edge portion of the substrate to be processed together with the adhesive sticking to the outer peripheral edge portion, and grinding a surface of a side opposite to the supporting substrate of the substrate to be processed whose outer peripheral edge portion is removed.

According to another embodiment, a substrate processing apparatus will be disclosed. The apparatus includes a remover for removing an outer peripheral edge portion of the substrate to be processed attached onto a supporting substrate via an adhesive layer together with the adhesive sticking to the outer peripheral edge portion, a grinder for grinding a surface of a side opposite to the supporting substrate of the substrate to be processed.

Hereinafter, the embodiments will be described with reference to the drawings. In description of the drawings below, the same reference numeral is given to the same elements or elements having the same function, and redundant explanation is omitted. Further, in the embodiments described below, explanation is each done with an example of a case that a substance to be processed is a semiconductor wafer, but it is a matter of course that the embodiments can be broadly applied to various substrates, not only to the semiconductor substrate, as long as the substrate is attached to a supporting substrate with an adhesive and is grinding-processed.

### First Embodiment

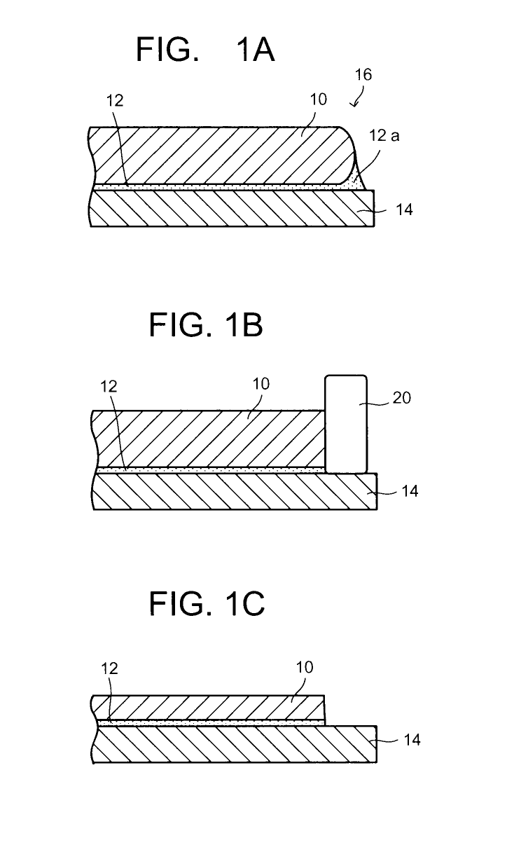

FIG. 1A to FIG. 1C are schematic cross-sectional views sequentially illustrating process steps of a substrate processing method of a first embodiment.

In the present embodiment, first, a semiconductor wafer 10 made of silicon or the like is prepared, and an adhesive is applied on an entire area of its one main surface (front surface) to form an adhesive layer 12. The semiconductor wafer 10 is then attached to a supporting substrate 14 made of glass, silicon or the like, so that a laminated substrate 16 is made (FIG. 1A). The semiconductor wafer 10 is not limited in particular and may be one having an orientation flat or one having a notch. Further, a shape of an outer peripheral edge portion is not limited in particular, and can be formed by any one of a flat surface, a curved surface, and a combination thereof (FIG. 1A to FIG. 1C illustrate an example of an outer peripheral edge portion having a curved surface).

The adhesive can be applied, for example, by using an application apparatus such as a spin coater which applies an adhesive while rotating the semiconductor wafer 10. Thus the adhesive layer 12 having an even thickness of, for example, about 20 to 50 μm may be formed on the one entire main surface of the semiconductor wafer 10. The semiconductor wafer 10 on which the adhesive layer 12 is formed is overlapped with an adhesive layer 12 side facing the supporting substrate 14. Thereby, the semiconductor wafer 10 is attached onto the supporting substrate 14 integrally in a state that a fillet 12a of the adhesive is formed in the outer peripheral edge portion of the semiconductor wafer 10.

Next, while the laminated substrate 16 is being rotated, the outer peripheral edge portion of the semiconductor wafer 10 and the adhesive sticking to the outer peripheral edge portion is removed by using a grinding blade 20 (FIG. 1B). A removed width, which depends on a shape or a diameter of the semiconductor wafer 10, a size (width of a part pressed out from the semiconductor wafer 10 of the adhesive) of the adhesive fillet 12a formed in the outer peripheral edge portion of the semiconductor wafer 10, or the like, is usually about 50 to 1000 preferably about 200 to 600 μm. More specifically, for example, for a semiconductor wafer 10 having a diameter of 300 mm, a width of about 600 μm from an adhesive fillet 12a end may be removed. By removing the outer peripheral edge portion of the semiconductor wafer 10 and the adhesive sticking to the outer peripheral edge portion in such a width, it is possible to solve various problems caused by the adhesive, such as, for example, contamination of a semiconductor wafer surface by fine particles or a volatile component, a damage of a grinding apparatus such as a grinding wheel to be used in thinning, and sticking fast to a dicing tape after grinding. It is also possible to solve a problem of a wafer crack caused by an occurrence of a knife edge in the outer peripheral edge portion of the semiconductor wafer.

Thereafter, a main surface (back surface) of a side opposite to the supporting substrate 14 of the semiconductor wafer 10 whose outer peripheral edge portion is removed is ground by using a grinding apparatus such as a grinding wheel, and further, a polishing processing such as CMP (chemical mechanical polishing) is performed as necessary, so that thinning to a targeted thickness is performed (FIG. 1C). If the adhesive sticking to the outer peripheral edge portion of the semiconductor wafer 10 is not completely removed in the above-described removing processing and a part thereof remains, the remaining adhesive is removed in the course of CMP. It should be noted that if a part of the adhesive 12 remains in the outer peripheral edge portion of the semiconductor wafer 10, a removing processing with an organic solvent may be performed prior to grinding of the back surface of the semiconductor wafer 10. This removing processing may be performed during or after grinding. The organic solvents include, but are not limited to, NMP (N-methyl-2-pyrrolidone) and mesitylene (1,3,5-trimethylbenzene).

As described above, in the present embodiment, since the outer peripheral edge portion of the semiconductor wafer and the adhesive sticking to the outer peripheral edge portion are removed after the semiconductor wafer is attached to the supporting substrate, it is possible to solve problems such as contamination of a semiconductor wafer 10 surface, a damage of a grinding wheel or the like used for grinding, and sticking fast to a dicing tape after grinding, the problems being conventionally caused by an adhesive pressed out to a surrounding area of a semiconductor wafer. Further, since removing of an outer peripheral edge portion of a semiconductor wafer has an effect similar to that of conventional edge trimming to a semiconductor wafer, an occurrence of a wafer crack can be prevented without performing edge trimming to a semiconductor wafer in advance, even in a case of reducing a thickness of the semiconductor wafer, so that a yield in a grinding processing can be improved.

### Second Embodiment

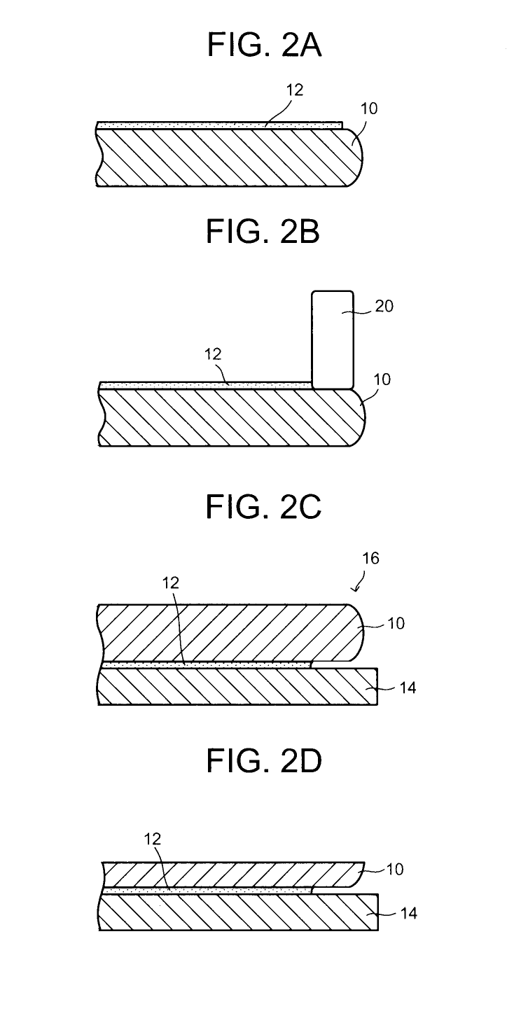

FIG. 2A to FIG. 2D are schematic cross-sectional views sequentially illustrating process steps of a substrate processing method of a second embodiment.

In the present embodiment, first, a semiconductor wafer 10 made of silicon or the like is prepared, and an adhesive is applied to an entire surface of its one main surface (front surface) thereby to form an adhesive layer 12 (FIG. 2A). The semiconductor wafer 10 to be used and a method for applying the adhesive are similar to those in the first embodiment.

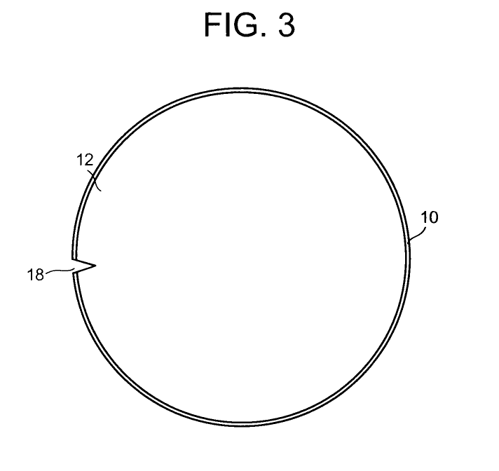

Next, while the semiconductor wafer 10 in which the adhesive layer 12 is formed is being rotated, a grinding blade 20 is pressed to an outer peripheral portion of the adhesive layer 12 and the adhesive layer 12 is grind-removed (FIG. 2B). A removed width of the adhesive layer 12 outer peripheral portion, the removed width depending on a size or the like of the semiconductor wafer 10, is usually about 50 to 1000 μm, preferably about 200 to 600 μm, and more specifically, for example, for a semiconductor wafer 10 having a diameter of 300 mm, removal is performed to a width of about 600 μm from an end portion. FIG. 3 is a top view of the semiconductor wafer 10 after the adhesive layer 12 outer peripheral portion is removed, seen from an adhesive layer 12 side. In FIG. 3, a reference numeral 18 indicates a notch provided in the semiconductor wafer 10.

In the present embodiment, though removal of the outer peripheral portion of the adhesive layer 12 is performed by the grinding blade 20, it is possible that an organic solvent is dropped or applied so that the dropped or applied organic solvent may dissolve the adhesive layer, thereby to perform chemical removal. Further, it is possible that such a chemical method and a physical method by a grinding blade can be combined to perform removal. As the organic solvent, for example, NMP, mesitylene or the like can be used.

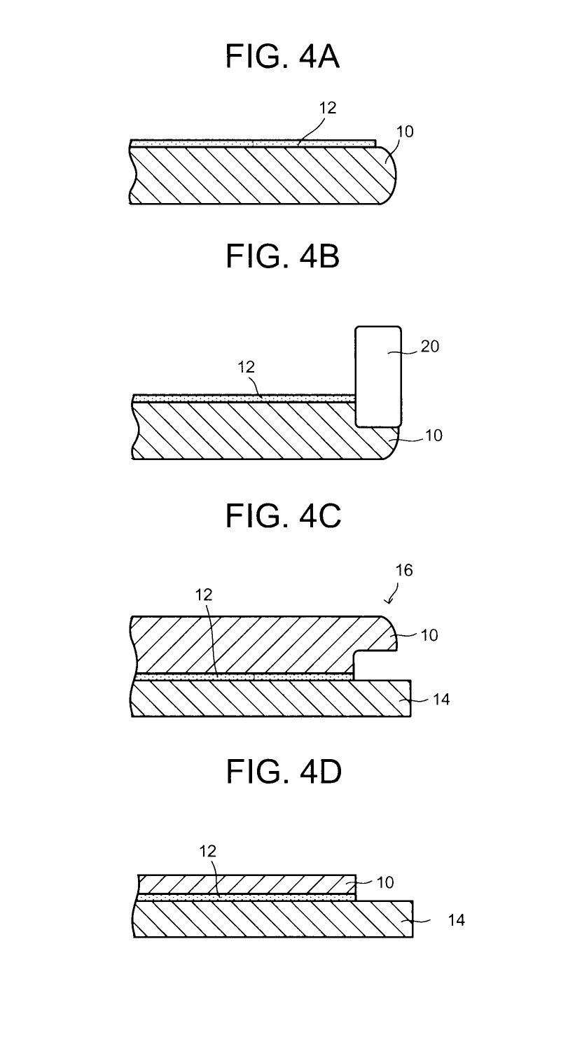

Further, though only the adhesive layer 12 is removed in the present embodiment, it is possible to grind as far as a semiconductor wafer 10 part as illustrated in FIG. 4A to FIG. 4D. By grinding as far as the semiconductor wafer 10 part as above, an adhesive pressed out to a wafer edge can be removed without physically destroying a supporting substrate 14 which will be described below. This is effective in particular in a case of a substrate material such as glass, which may be used repeatedly by washing.

Next, the above-described semiconductor wafer 10 is overlapped with its adhesive layer 12 side facing the supporting substrate 14 and attached to the supporting substrate 14 made of glass, silicon or the like, so that a laminated substrate 16 is made (FIG. 2C).

Thereafter, a main surface (back surface) in a side opposite to the supporting substrate 14 of the semiconductor wafer 10 is ground by using a grinding apparatus such as a grinding wheel, and further, a polishing processing such as CMP may be performed as necessary, so that thinning to a targeted thickness is performed (FIG. 2D).

In the present embodiment, since the outer peripheral portion of the adhesive layer 12 formed in the entire front surface of the semiconductor wafer 10 is removed before the semiconductor wafer 10 is attached to the supporting substrate 14, it is possible to solve problems such as contamination of a semiconductor wafer 10 surface, a damage of a grinding wheel or the like used for grinding, and sticking fast to a dicing tape after grinding, the problems being conventionally caused by an adhesive pressed out to a surrounding area of a semiconductor wafer 10.

In this embodiment, if a thickness of a semiconductor wafer 10 is thinned to be, for example, equal to or less than 100 there is an apprehension that a knife edge is formed in an end portion of the semiconductor wafer 10 thereby causing a wafer crack. Therefore, in such a case, it is preferable to use a semiconductor wafer having been edge-trimmed in advance as the semiconductor wafer 10.

According to at least one embodiment described hereinabove, when grinding a semiconductor wafer attached to a supporting substrate with an adhesive, since the adhesive is not pressed out to a surrounding area of the semiconductor wafer, a grinding apparatus such as a grinding wheel does not grind the adhesive, so that a damage of the grinding apparatus by the adhesive and concurrent reduction of an operating life characteristic can be prevented. Further, since the adhesive does not remain in the surrounding area of the semiconductor wafer after grinding, a problem of contamination of a wafer surface by fine particles or a volatile component does not occur. Further, also at a time that a dicing tape is applied to the semiconductor wafer thereby to release the semiconductor wafer from the supporting substrate after grinding, since the adhesive does not exist in the surrounding area of the semiconductor wafer, it is avoided that the supporting substrate becomes hard to be released due to adhesion of the dicing tape to the adhesive.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate processing method, comprising:
attaching a substrate to be processed onto a supporting substrate via an adhesive layer;
removing an outer peripheral edge portion of the substrate to be processed together with the adhesive sticking to the outer peripheral edge portion; and
grinding a surface of a side opposite to the supporting substrate of the substrate to be processed whose outer peripheral edge portion is removed.

2. The method of claim 1, wherein the substrate to be processed is attached onto the supporting substrate such that a fillet of the adhesive is formed on the outer peripheral edge portion of the substrate to be processed.

3. The method of claim 1, wherein the adhesive layer has a thickness of 20 to 50 μm.

4. The method of claim 1, wherein the removed width of the adhesive layer is 50 to 1000 μm.

5. The method of claim 1, wherein the removing of the outer peripheral edge portion of the substrate to be processed is performed by grinding.

6. The method of claim 5, further comprising:
removing a remaining portion of the adhesive sticking to the outer peripheral edge portion after grinding.

7. The method of claim 1, further comprising:
polishing the ground surface of the substrate.

8. The method of claim 1, wherein the ground substrate has a thickness of 100 μm or less.

9. The method of claim 1, wherein the substrate to be processed is a semiconductor wafer.

10. A substrate processing apparatus, comprising:
a remover for removing an outer peripheral edge portion of the substrate to be processed attached onto a supporting substrate via an adhesive layer together with the adhesive sticking to the outer peripheral edge portion;
a grinder for grinding a surface of a side opposite to the supporting substrate of the substrate to be processed.

11. A substrate processing method, comprising:
forming an adhesive layer on an entire main surface of the substrate to be processed;
removing selectively an outer peripheral edge portion of the adhesive layer;
attaching the substrate to be processed onto a supporting substrate; and
grinding a surface of a side opposite to the supporting substrate of the substrate to be processed.

12. The method of claim 11, wherein the adhesive layer has a thickness of 20 to 50 μm.

13. The method of claim 11, wherein the removed width of the outer peripheral edge portion of the adhesive layer is 50 to 1000 μm.

14. The method of claim 11, wherein the outer peripheral edge portion of the adhesive layer is removed chemically and/or physically.

15. The method of claim 11, wherein the outer peripheral edge portion of the adhesive layer is removed by grinding from the surface side of the adhesive layer towards the substrate to be processed.

16. The method of claim 11, wherein the outer peripheral edge portion of the substrate to be processed is removed together with the outer peripheral edge portion of the adhesive layer.

17. The method of claim 11, wherein the outer peripheral edge portion of the semiconductor wafer is edge-trimmed before the adhesive layer is formed.

18. The method of claim 11, wherein the ground substrate has a thickness of 100 μm or less.

19. The method of claim 11, wherein the substrate to be processed is a semiconductor wafer.
